(19) United States
(12) Patent Application Publication
(10) Pub. No.: US 2026/0052637 A1
(43) Pub. Date: Feb. 19, 2026

(54) ELECTRONIC CONTROL DEVICE

(71) Applicant: HITACHI ASTEMO, LTD., Hitachinaka-shi, Ibaraki (JP)

(72) Inventors: Yuichiro YOSHITAKE, Hitachinaka-shi, Ibaraki (JP); Yukio HATTORI, Hitachinaka-shi, Ibaraki (JP); Masao FUJIMOTO, Hitachinaka-shi, Ibaraki (JP); Tomio SAKASHITA, Hitachinaka-shi, Ibaraki (JP); Haruaki MOTODA, Hitachinaka-shi, Ibaraki (JP)

(73) Assignee: HITACHI ASTEMO, LTD., Hitachinaka-shi, Ibaraki (JP)

(21) Appl. No.: 19/102,725

(22) PCT Filed: Jun. 6, 2023
(86) PCT No.: PCT/JP2023/020914

§ 371 Date: Feb. 10, 2025

(30) Foreign Application Priority Data
Aug. 12, 2022 (JP) 2022-128690

(51) Int. Cl. H05K 7/14; H02M 7/00

(52) U.S. Cl. CPC H05K 7/14324; H02M 7/003; H05K 7/14329

(57) ABSTRACT

In an electronic control device (E1) according to the present invention, in one aspect thereof, for example, noise filter capacitors (53m) (53s) and smoothing capacitors (54m) (54s) that are capacitors occupying a relatively large mounting area are disposed not on a circuit board (30) but rather on a second side surface (412) of a connector base (41). With this, it is possible to reduce the mounting area of the circuit board (30) by the amount of the noise filter capacitors (53m) (53s) and the smoothing capacitors (54m) (54s), and thereby the size of the electronic control device (E1) can be reduced.

### TECHNICAL FIELD

The present invention relates to an electronic control device.

### BACKGROUND TECHNOLOGY

An example of a conventional electronic control device is known, for example, as described in the following patent document 1.

In brief, this electronic control device constitutes a so-called redundant system (dual system), and a smoothing capacitor that constitutes one of the power modules in the dual system is arranged on the outer side surface of a bus bar holder, which is arranged to overlap a control board.

### PRIOR ART REFERENCE(S)

### Patent Document(S)

Patent Document 1: Japanese Patent Application Publication No. 2020-188638

### SUMMARY OF THE INVENTION

### Problem to be Solved by the Invention

However, in the above-mentioned conventional electronic control device, while the number of connector ports increases with the configuration of the redundant system, the placement area of connectors decreases due to the mounting of so-called filter components such as the smoothing capacitor mentioned above. Due to this, there is room for improvement in that it has become a detriment to the miniaturization of the device.

The present invention has been made in consideration of such a technical problem of the above-mentioned conventional electronic control device, and an object of the present invention is to provide an electronic control device that can reduce the size of the device.

### Means for Solving the Problem

The present invention, in one aspect thereof, is one in which a capacitor is mounted on the second side surface of a connector base which faces a power conversion circuit module or power conversion circuit board.

### Effect of the Invention

According to the present invention, it is possible to reduce the size of the electronic control device.

### BRIEF DESCRIPTION OF THE DRAWINGS

FIG. 1 is a longitudinal sectional view of an electronic control device according to a first embodiment of the present invention.

FIG. 2 is an enlarged view of a main part of FIG. 1.

FIG. 3 is one corresponding to FIG. 2, and there is shown another example of the first embodiment in the present embodiment.

FIG. 4 is a sectional view taken along an A-A line of FIG. 1.

FIG. 5 is a sectional view taken along a B-B line of FIG. 1.

FIG. 6 is a sectional view taken along a C-C line of FIG. 1.

FIG. 7 is a longitudinal sectional view of an electronic control device according to a second embodiment of the present invention.

FIG. 8 is a sectional view taken along a D-D line of FIG. 7.

FIG. 9 is a sectional view taken along an E-E line of FIG. 7.

FIG. 10 is a sectional view taken along an F-F line of FIG. 7.

FIG. 11 is one corresponding to FIG. 9, and there is shown a first variation of the second embodiment in the present invention.

FIG. 12 is one corresponding to FIG. 9, and there is shown a second variation of the second embodiment in the present invention.

### Mode for Implementing the Invention

In the following, an embodiment of an electronic control device according to the present invention will be explained in detail based on the drawings. In addition, in the present embodiment, an example is shown in which the electronic control device according to the present invention is applied to a motor unit mounted in an electric power steering system of an automobile, especially in a power steering system with a redundant system (in this embodiment, a dual system). In addition, most electronic components that constitute the redundant system are described with “m” and “s” at the end of the reference signs.

### FIRST EMBODIMENT

(Configuration of Electronic Control Device)

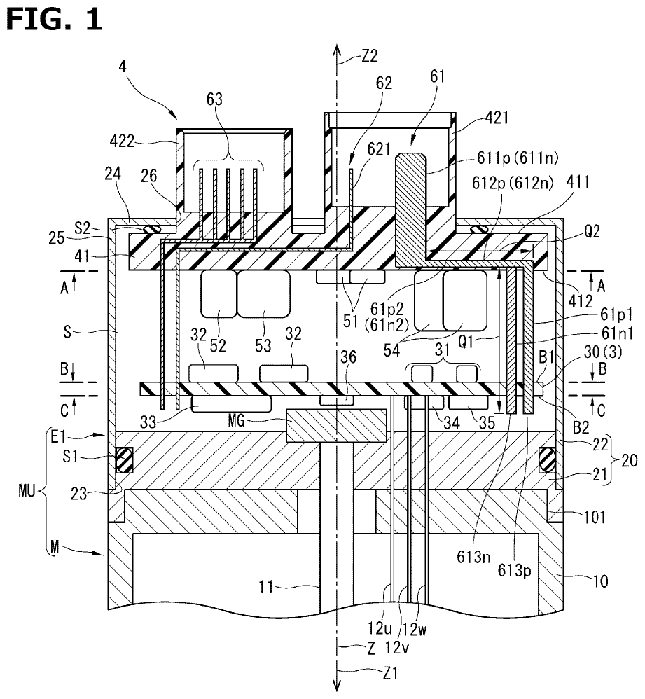

FIG. 1 shows an electronic control device E1 according to a first embodiment of the present invention, and shows a longitudinal sectional view of a motor unit MU configured integrally with the electronic control device E1 and a motor M, the longitudinal sectional view which is cut along the direction of a rotational axis Z of the motor M. In addition, in the explanation of FIG. 1, for convenience, the side in the axial direction where the motor M is disposed is referred to as a “first end side Z1” and the side where the electronic control device E1 is disposed is referred to as a “second end side Z2.

For example, as shown in FIG. 1, the electronic control device E1 according to the present embodiment is arranged in series on the second end side Z2 of the motor M, which is to be controlled, and is configured integrally with the motor M as a so-called electromechanical device. Then, the motor unit MU, which is composed of the electronic control device E1 and the motor M, is mounted on the power steering system, which is not shown, to generate assist torque in response to the input torque input from the steering wheel, which is not shown, to assist the steering operation of the driver.

The motor M is, for example, a three-phase AC brushless motor and is provided with a substantially cylindrical motor housing 10, a motor element, which is not shown, housed inside the motor housing 10, and a motor rotation shaft 11 driven by the motor element. Power and drive control signals are supplied to the motor M via the electronic control device E1 attached to the motor M, and the motor M is driven and controlled based on the power and drive control signals supplied via the electronic control device E1.

The motor housing 10 is formed in a substantially cylindrical shape and is made of a metal material having relatively excellent heat dissipation properties, such as aluminum alloy material, and has a housing space thereinside which has a substantially circular cross-sectional shape extending along the axial direction. In addition, the motor housing 10 is provided with an ECU connection portion 101 at the end portion facing the electronic control device E1, the ECU connection portion 101 with a diameter which is stepwisely reduced toward the first end side Z1. A first housing 21 of the ECU housing 20 which is described below is fitted to the ECU connection portion 101 so as to be fixed.

Although the motor element not shown, which is housed in the motor housing 10, has a well-known configuration and specific illustrations are omitted, it has a stator in which a coil (three-phase winding of U-, V-, and W-phase) is wound around an iron core (teeth), and a cylindrical rotor rotatably housed on the inner circumference side of the stator via a predetermined space and provided with a plurality of permanent magnets on the outer circumference side such that magnetic poles alternately change in the circumferential direction.

One end side in the axial direction (first end side Z1) of the motor rotation shaft 11 is connected to the steering shaft, rack shaft and the like of the power steering device, which is not shown, via a reduction mechanism (for example, a worm gear), which is not shown. On the other hand, a well-known sensor magnet MG is attached to the end portion on the other end side (second end side Z2) of the motor rotation shaft 11, and the rotation position (rotation angle) of the motor rotation shaft 11 is detected via this sensor magnet MG.

The electronic control unit E1 is formed in a substantially cylindrical shape with an outer diameter approximately the same as that of the motor M and is connected to the second end side Z2 of the motor M. Specifically, the electronic control device E1 has an ECU housing 20 as a casing attached to the end portion on the second end side Z2 of the motor housing 10, a circuit module 3 housed in a housing space S formed in the ECU housing 20, and a connector module 4 which is connected to the circuit module 3 and supplies power to the power conversion circuit (not shown) described below.

In addition, in the present embodiment, as an example, a mode is shown in which the power conversion circuit and the control circuit, which are not shown in the drawings, are provided on a single circuit board 30 in a single circuit module 3, but the power conversion circuit may be provided on a power conversion circuit board, which is not shown, provided separately (independently) from the control board on which the control circuit not shown is formed.

The ECU housing 20 has a first housing 21, which is a mounting base fitted and fixed to the end portion on the second end side Z2 of the motor housing 10, and a second housing 22, which is a cover fitted and attached to the second end side Z2 of the first housing 21.

The first housing 21 is formed in a substantially disk-like shape and made of a metal material and functions as a mounting base for the circuit board 30 as well as a heat sink to dissipate the heat generated by the electronic components mounted on the circuit board 30. In addition, an annular first sealing member S1, such as an O-ring, is interposed between the first housing 21 and the second housing 22, and the outer circumference surface of the first housing 21 and the inner circumference surface of the second housing 22 are liquid-tightly sealed by the first sealing member S1.

The second housing 22 is made of a metal or synthetic resin material and is formed in a cylindrical shape such that one end side (first end side Z1) in the axial direction is opened and the other end side (second end side Z2) in the axial direction is closed. Specifically, the second housing 22 has an opening portion 23 opening to the first end side Z1, a bottom wall 24 closing the second end side Z2, and a cylindrical side wall 25 rising substantially vertically from the outer circumferential edge of the bottom wall 24 so as to extend toward the first end side Z1. In addition, the bottom wall 24 of the second housing 22 has a connector insertion hole 26 through which a first connector port 421 and a second connector port 422 described below of the connector module 4 pass to expose the first connector port 421 and second connector port 422 to the outside.

In addition, between the second housing 22 and a connector base 41 of the connector module 4 which is described below, an annular second sealing member S2, such as an O-ring, is interposed in the area on the outer circumference side of the connector insertion hole 26. In other words, the second sealing member S2 suppresses foreign matter from entering into the inside of the second housing 22 from the outside of the second housing 22 through the connector insertion hole 26.

The circuit module 3 is composed of a circuit board 30, which is a single multilayer printed circuit board having a substantially disc-like shape, and an inverter circuit, which is the above-mentioned power conversion circuit not shown, is formed on a first surface B1 of the circuit board 30 which faces the connector module 4, and various electronic components, such as a plurality of switching elements 31 that constitute the inverter circuit and pre-drivers 32 as drive circuit components that drive and control the switching elements 31, are mounted for each of the three phase windings of the motor M as a drive system that can drive the motor M. On the other hand, on a second surface B2 of the circuit board 30 which faces the motor M, for example, the above-mentioned motor control circuit not shown is formed, and a microcomputer 33 (hereinafter is referred to as a “microcomputer”) that controls the drive control of the motor M is provided, and a power relay 34 provided for supplying power, a signal relay 35 provided for inputting external signals, and a rotation angle sensor 36 provided for detecting the rotation angle of the motor rotation shaft 11 are mounted. In addition, U-phase, V-phase, and W-phase connection terminals (winding terminals), 12u, 12v, and 12w, which are U-phase, V-phase, and W-phase connection terminals connected to the motor M, are connected to the above-mentioned motor control circuit, which is formed on the second surface B2 of the circuit board 30 and is not shown.

The connector module 4 has a substantially disc-shaped connector base 41 which is housed inside the second housing 22, and a first connector port 421 and a second connector port 422, which are a plurality of connector ports protruding from a first side surface 411 (end surface of the second end side Z2) of the connector base 41 which faces the bottom wall 24 of the second housing 22. The connector base 41, the first connector port 421 and the second connector port 422 are integrally formed by a synthetic resin material.

The connector base 41 buries inside part of each of a power supply line 61, a CAN communication line 62, and sensor signal lines 63 exposed outside the second housing 22 via the first and second connector ports 421 and 422, and introduces them into the housing space S in the ECU housing 20. In addition, the connector base 41 is co-fastened and fixed together with the circuit board 30 to the first housing 21 via a fastening member not shown, such as a screw. In addition, a plurality of switching elements 51, a plurality of noise filter coils 52, a plurality of noise filter capacitors 53, and a plurality of smoothing capacitors 54 are arranged on a second side surface 412 of the connector base 41 which faces the circuit board 30. Although not shown in the drawings, the smoothing capacitors 54 may be configured to be held by a well-known capacitor holder.

The first and second connector ports 421 and 422 are exposed to the outside of the second housing 22 and are used for connection to a power supply and various communication lines not shown. Specifically, the first connector port 421 has a relatively large opening square cylindrical shape, through which a flat power supply terminal 611 of the power supply line 61, which is connected to the circuit board 30, and a CAN communication terminal 621 of the CAN communication line 62 are inserted. On the other hand, the second connector port 422 has a relatively small opening square cylindrical shape, and various sensor signal lines 63 such as a steering angle sensor and a torque sensor, which are not shown, are inserted therethrough.

Here, the power supply line 61 is composed of a pair of metal bus bars and has a P-side bus bar 61p and a N-side bus bar 61n. The P-side bus bar 61p and N-side bus bar 61n each have a flat shape and have a relatively wide P-side first plane part 61p1 and N-side first plane part 61n1, respectively, and a relatively narrow P-side second plane part 61p2 and N-side second plane part 61n2, respectively, and are arranged parallel to each other. Then, the P-side bus bar 61p and N-side bus bar 61n each are mainly composed of three parts by bending the middle part, and the P-side bus bar 61p has a P-side connector connection terminal 611p, a P-side buried part 612p, a P-side board connection part 613p and the N-side bus bar 61n has an N-side connector connection terminal 611n, an N-side buried part 612n and an N-side board connection part 613n.

The P-side connector connection terminal 611p and the N-side connector connection terminal 611n extend in a straight line on the first side 411 side of the connector base 41 in a direction orthogonal to the connector base 41 and are exposed externally from the first connector port 421. The P-side buried part 612p and N-side buried part 612n are buried inside the connector base 41 such that they are bent substantially at a right angle to the P-side connector connection terminal 611p and N-side connector connection terminal 611n and extend straight inside the connector base 41 parallel to the connector base 41. The P-side board connection part 613p and the N-side board connection part 613n are bent substantially at a right angle to the P-side buried part 612p and the N-side buried part 612n and extend straight from the second side surface 412 side of the connector base 41 in a direction orthogonal to the connector base 41, and then are connected to the circuit board 30.

Here, the relatively wide plane parts of the respective P-side bus bar 61p and N-side bus bar 61n, namely, the P-side first plane part 61p1 and N-side first plane part 61n1 face each other. On the other hand, the relatively narrow plane parts of the respective P-side buried part 612p and the N-side buried part 612n, namely, the P-side second plane part 61p2 and the N-side second plane part 61n2 face each other. In addition, in the present embodiment, the P-side bus bar 61p and N-side bus bar 61n are configured such that a first region Q1 where the P-side first plane part 61p1 and the N-side first plane part 61n1 face each other is longer than a second region Q2 where the P-side second plane part 61p2 and the N-side second plane part 61n2 face each other.

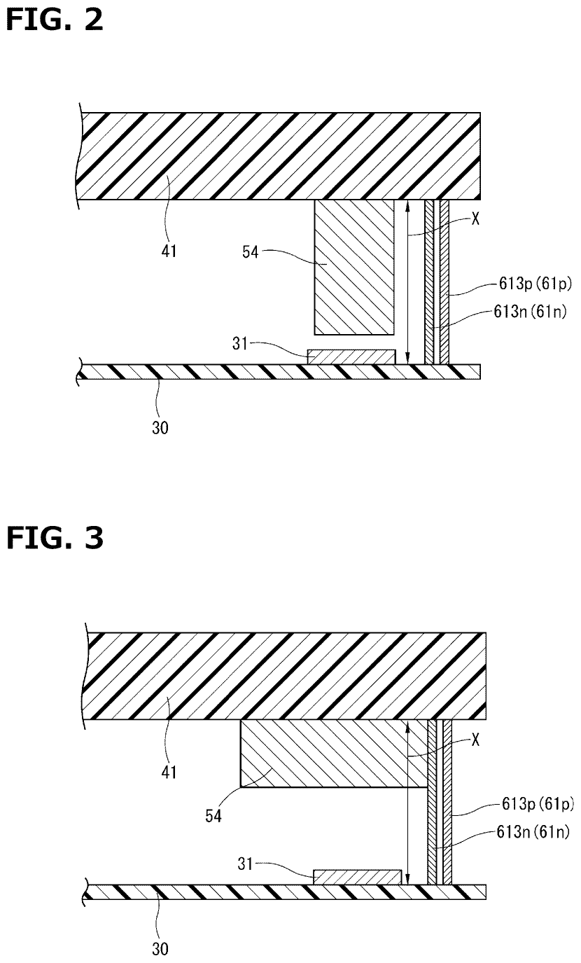

FIG. 2 shows an enlarged view of a main part of FIG. 1 in which the vicinity of the P-side board connection part 613p and N-side board connection part 613n is enlarged. In addition, FIG. 3 shows another example of an enlarged view of the main part of FIG. 1 which is shown in FIG. 2.

As shown in FIG. 2, in the electronic control device E1 according to the present invention, the smoothing capacitor 54 disposed on the second side surface 412 of the connector base 41 and the switching element 31 disposed on the first surface B1 of the circuit board 30 are arranged facing and to be close to each other. Moreover, in the area where the smoothing capacitor 54 and the switching element 31 are adjacent to each other, the P-side substrate connection part 613p and the N-side substrate connection part 613n are arranged facing and to be close to each other. Accordingly, in the present embodiment, the smoothing capacitor 54 disposed on the connector base 41 and the switching element 31 disposed on the circuit board 30 are disposed at a very narrow distance from each other, and the P-side board connection part 613p and N-side board connection part 613n are disposed at a very narrow distance from each other at a position close to the smoothing capacitor 54 and the switching element 31.

In other words, in the present embodiment, the distance between the smoothing capacitor 54 and the switching element 31 is shortened as much as possible by shortening a wiring length X of the P-side board connection part 613p and N-side board connection part 613n as much as possible. Consequently, the switching time of each of the switching elements 31 is reduced, and the heat generated by the switching of each of the switching elements 31 can be reduced.

In addition, although in the present embodiment, in consideration of reducing the mounting area of the smoothing capacitors 54 in the connector base 41, as shown in FIG. 2, the example shows the arrangement of a smoothing capacitor 54 in a vertical position (such that its longitudinal direction is parallel to the rotational axis Z of the motor M, namely, orthogonal to the connector base 41), it is not limited to this arrangement. In other words, the smoothing capacitors 54 may be arranged horizontally (such that its longitudinal direction is orthogonal to the rotational axis Z of the motor M, namely, parallel to the connector base 41), as shown in FIG. 3. In this case, depending on the relationship with other electronic components, the distance between the connector base 41 and the circuit board 30 can be further reduced, which has the advantage of further shortening the wiring length X of the P-side board connection part 613p and N-side board connection part 613n.

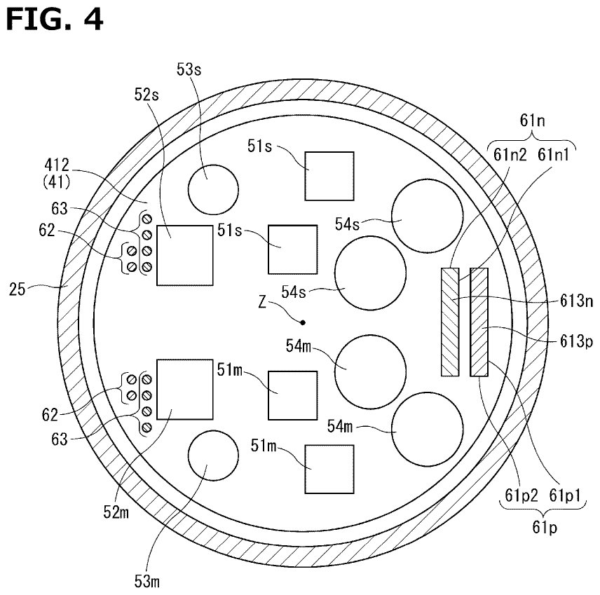

FIG. 4 is a sectional view taken along an A-A line of FIG. 1, and there is shown a cross-section of the electronic control device E1 viewed from the second side surface 412 side of the connector base 41.

As shown in FIG. 4, the connector module 4 has a plurality (a pair) of noise filter coils 52m and 52s and a plurality (a pair) of noise filter capacitors 53m and 53s mounted on the second side surface 412 of the connector base 41, in the area on the left side of the rotational axis Z of the motor M (motor rotation shaft 11) in FIG. 4. In addition, outside of the pair of the noise filter coils 52m and 52s, a plurality of CAN communication line insertion holes 43 through which a plurality of CAN communication lines 62 are inserted and a plurality of sensor signal line insertion holes 44 through which a plurality of sensor signal lines 63 are inserted pass through along the axial direction.

In addition, in the second side surface 412 of the connector base 41, a plurality of switching elements 51m and 51s (four in the present embodiment) are arranged in the area on the right side of the rotational axis Z of the motor M (motor rotation shaft 11) in FIG. 4. Moreover, on the second side surface 412 of the connector base 41, a plurality of smoothing capacitors 54m and 54s (four in this embodiment) are arranged outside of the switching elements 51, and a plurality of P-side bus bar insertion holes 45p through which the P-side board connection part 613p is inserted and a pair of N-side bus bar insertion holes 45n through which the N-side board connection part 613n is inserted are arranged outside of the smoothing capacitors 54m and 54s.

Here, the P-side bus bar insertion holes 45p and N-side bus bar insertion holes 45n are arranged facing each other along the radial direction of the second side surface 412 of the connector base 41 and are arranged close to the smoothing capacitors 54. In addition, the P-side bus bar insertion holes 45p and the N-side bus bar insertion holes 45n are arranged such that the wide P-side first plane part 61p1 of the P-side board connection part 613p and the wide N-side first plane part 61n1 of the N-side board connection part 613n face each other and the P-side first plane part 61p1 and N-side first plane part 61n1 are close together.

More specifically, the P-side bus bar insertion holes 45p and N-side bus bar insertion holes 45n are arranged to be close to each other with a width W1 of the P-side first plane part 61p1 and N-side first plane part 61n1, which is relatively wide as compared with the width of the P-side board connection part 613p and N-side board connection part 613n, or with a space smaller than a width W2 of the P-side second plane part 61p2 and N-side second plane part 61n2, which is relatively narrow as compared with the width of the P-side board connection part 613p and N-side board connection part 613n.

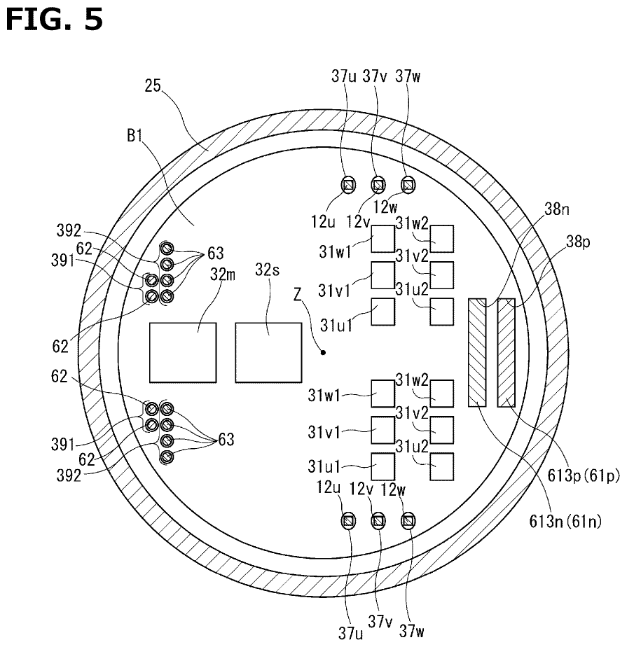

FIG. 5 is a sectional view taken along a B-B line of FIG. 1, and there is shown a cross section of the electronic control device E1 viewed from the first surface B1 side of the circuit board 30.

As shown in FIG. 5, on the first surface B1 of the circuit board 30, in the area on the left side of the rotational axis Z of the motor M (motor rotation shaft 11) in FIG. 5, a plurality (a pair) of pre-drivers 32m and 32s are arranged along the radial direction. In addition, in the circuit board 30, on the outer side of the pair of the pre-drivers 52m and 52s, a plurality of CAN communication line insertion holes 391 through which a plurality of CAN communication lines 62 are inserted and a plurality of sensor signal line insertion holes 392 through which a plurality of sensor signal lines 63 are inserted pass through along the axial direction.

On the other hand, on the first surface B1 of the circuit board 30, in the area on the right side of the rotational axis Z of the motor M (motor rotational shaft 11) in FIG. 5, first switching elements 31u1, 31v1 and 31w1 are paired with second switching elements 31u2, 31v2 and 31w2, respectively, which constitute the inverter circuit used to drive and control the 3-phase motor M, and the first switching elements 31u1, 31v1 and 31w1 and the second switching elements 31u2, 31v2 and 31w2 are arranged above and below the rotation axis Z of the motor M (motor rotation shaft 11) so as to face the smoothing capacitors 54 disposed at the connector base 41. Specifically, the paired first switching elements 31u1, 31v1 and 31w1 and second switching elements 31u2, 31v2 and 31w2 are arranged such that the switching elements for the corresponding phases face each other, and the first switching elements 31u1, 31v1 and 31w1 are arranged on the inside and the second switching elements 31u2, 31v2 and 31w2 are arranged on the outside.

In addition, on the circuit board 30, in the parallel direction of the first switching elements 31u1, 31v1 and 31w1, U-phase terminal insertion holes 37u, V-phase terminal insertion holes 37v and W-phase terminal insertion holes 37w are formed through which U-phase connection terminals 12u, 12v, and 12w which are three-phase (U phase, V phase, W phase) connection terminals (winding terminals) extending from the motor M side are inserted, so as to pass therethrough, on the outer side of the first switching elements 31u1, 31v1, and 31w1.

In addition, on the first surface B1 of the circuit board 30, in the area on the outer circumferential side of the second switching elements 31u2, 31v2 and 31w2 with respect to the rotation axis Z of the motor M (motor rotation shaft 11) and at positions corresponding to the P-side bus bar insertion holes 45p and N-side bus bar insertion holes 45n in the connector base 41, a pair of P-side bus bar insertion hole 38p and N-side bus bar insertion hole 38n, through which the P-side board connection part 613p and N-side board connection part 613n are inserted, are formed close to and facing each other so as to penetrate therethrough, similar to the P-side bus bar insertion holes 45p and N-side bus bar insertion holes 45n in the connector base 41.

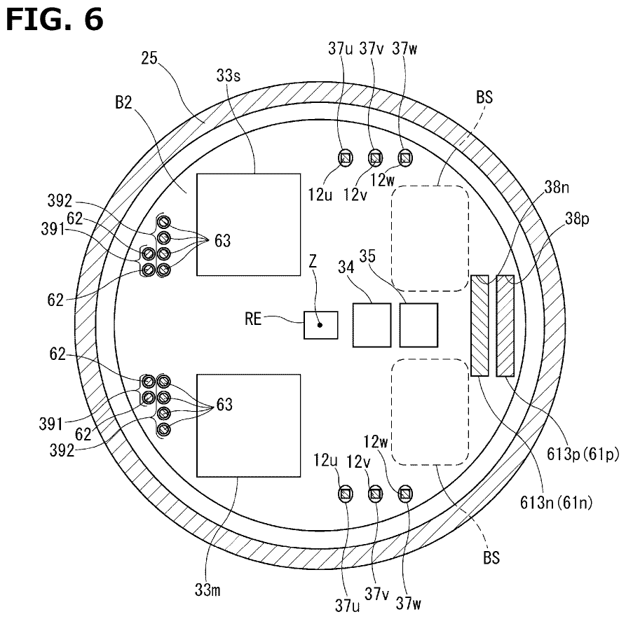

FIG. 6 is a sectional view taken along a C-C line of FIG. 1, and there is shown a cross section of the electronic control device E1 viewed from the second surface B2 side of the circuit board 30.

As shown in FIG. 6, on the second surface B2 of the circuit board 30, a plurality (a pair) of microcontrollers 33m and 33s are arranged symmetrically above and below the rotation axis Z of the motor M (motor rotation shaft 11) in the area on the left side of the motor M (motor rotation shaft 11) in FIG. 6. Moreover, a rotation angle sensor RE that detects the rotation phase and speed of the motor rotation shaft 11 in cooperation with a sensor magnet MG provided to the motor rotation shaft 11 is disposed in the center of the second surface B2 of the circuit board 30. Further, a power relay 34 and signal relay 35 are disposed adjacent to each other along the radial direction in the area on the right side of the rotation axis Z of the motor M (motor rotation shaft 11) in FIG. 6 on the second surface B2 of the circuit board 30.

In addition, the second surface B2 of the circuit board 30 has an open space BS on each of both sides of the power relay 34 and signal relay 35, in the area on the left side of the rotation axis Z of the motor M (motor rotation shaft 11) in FIG. 6. This open space BS may be used for cooling the inverter circuit (not shown) formed on the second surface B2 of the circuit board 30 by bringing the inverter circuit (not shown) in contact with the first housing 21 that serves as a heat sink. In addition, the open space BS can also be used as a mounting space for other electronic components (not shown).

### EFFECTS of the present embodiment

In the above-mentioned conventional electronic control devices, while the number of connector ports increases with the configuration of the redundant system, the area where connector ports can be disposed decreases because so-called filter components such as smoothing capacitors are mounted on the circuit board. In particular, when a redundant system is configured, electronic components are mounted in multiples of the number of systems, and a larger mounting area is required. Therefore, the fact that as in the above-mentioned conventional electronic control devices, filter components such as smoothing capacitors, which occupy a relatively large area, are mounted on the circuit board has caused a negative effect on the miniaturization of the electronic control devices, and there is still room for improvement.

In contrast to this, according to the electronic control device E1 according to the present embodiment, the following effects can be achieved, thereby solving the problems of the conventional electronic control devices mentioned above.

The electronic control device E1 is an electronic control device having a power conversion system which converts the power of a power source into drive power to drive a rotating electrical machine (motor M in the present embodiment), and is provided with a power conversion circuit module or power conversion circuit board (circuit board 30 in the present embodiment) on which the power conversion circuit constituting the power conversion system is formed, a casing (ECU housing 20 in the present embodiment) which has a housing space S thereinside and houses a circuit board 30, a connector module 4 which has a connector base 41 that is housed in the housing space S together with the circuit board 30, and connector ports (first connector port 421 and second connector port 422 in the present embodiment) which are formed protruding from a first side surface 411 of the connector base 41 and face outside the ECU housing 20, and capacitors (noise filter capacitors 53m and 53s and smoothing capacitors 54m and 54s in the present embodiment) mounted on a second side surface 412 of the connector base 41, which faces the circuit board 30 and is positioned on the opposite side of the first side surface 411, and used for power smoothing or noise reduction of a power supply line 61 leading from the connector port (first connector port 421 in present embodiment) to the power conversion circuit.

In this way, in the present embodiment, the noise filter capacitors 53m and 53s and smoothing capacitors 54m and 54s, which are capacitors with relatively large mounting area occupancy, are not disposed on the circuit board 30, but on the second side surface 412 of the connector base 41. Consequently, the mounting area of the circuit board 30 can be reduced by the amount of the noise filter capacitors 53m and 53s and smoothing capacitors 54m and 54s disposed in the connector base 41, and the size of the electronic control device E1 can be reduced.

In addition, in the present embodiment, the power supply line 61 is composed of conductive bus bars (P-side bus bar 61p and N-side bus bar 61n in the present embodiment), and the P-side bus bar 61p and N-side bus bar 61n are provided extending through the inside of the connector module 4 from the connector port (first connector port 421 in the present embodiment) so as to face the housing space S of the ECU housing 20 from the second side surface 412 of the connector base 41, and are connected to the circuit board 30. In addition, on the second side surface 412 of the connector module 4, in addition to the capacitors (noise filter capacitors 53m and 53s and smoothing capacitors 54m and 54s in the present embodiment), other electronic components (switching elements 51m and 51s and noise filter coils 52m and 52s in the present embodiment correspond) are mounted. Moreover, on the second side surface 412 of the connector module 4, the capacitors (smoothing capacitors 54m and 54s in the present embodiment) are arranged closer to the P-side bus bar 61p and N-side bus bar 61n facing the housing space S than the other electronic components mentioned above.

Here, an inductance L between parallel plate conductors is obtained based on the formula “L (inductance)=μ(magnetic permeability)×d(facing distance of plates)/W(width of facing plates). That is, according to the formula, the smaller the facing distance d between the flat conductors is, the smaller the inductance L is, and the larger the width W of the facing flat conductors is, the smaller the inductance L is. In addition, the smaller the wiring length of a flat conductor, namely, the smaller the distance between a switching element and a filter component (capacitor) connected by the flat conductors is, the smaller the inductance L is.

Therefore, in the present embodiment, the smoothing capacitors 54m and 54s are arranged closer to the P-side bus bar 61p and N-side bus bar 61n than the other electronic components that are the switching elements 51m and 51s and noise filter coils 52m and 52s. With this, the inductance L between the P-side bus bar 61p and N-side bus bar 61n is reduced, and the mounting area of the smoothing capacitors 54m and 54s can be reduced on the second side surface 412 of the connector base 41, and thereby the size of the electronic control device E1 can further be reduced.

In addition, in the present embodiment, the power supply line 61 is composed of conductive bus bars (P-side bus bar 61p and N-side bus bar 61n in the present embodiment), and the P-side bus bar 61p and N-side bus bar 61n are provided extending through the inside of the connector module 4 from the connector port (first connector port 421 in the present embodiment) so as to face the housing space S of the ECU housing 20 from the second side surface 412 of the connector base 41, and are connected to the circuit board 30. In addition, the power conversion circuit has a plurality of switching elements, and the circuit board 30 is mounted with other electronic components (a plurality of pre-drivers 32m and 32s in the present embodiment) together with a plurality of switching elements (first switching elements 31u1, 31v1 and 31w1 and second switching elements 31u2, 31v2 and 31w2 in the present embodiment). Moreover, on the second side surface 412 of the connector module 4, at least one of the first switching elements 31u1, 31v1 and 31w1 and second switching elements 31u2, 31v2 and 31w2 is arranged closer to the exposed wiring parts (the P-side board connection part 613p and N-side board connection part 613n in the present embodiment) of the P-side bus bar 61p and N-side bus bar 61n which face the housing space S than the other electronic components mentioned above.

In this way, in the present embodiment, at least one of the first switching elements 31u1, 31v1 and 31w1 and second switching elements 31u2, 31v2 and 31w2 is arranged closer to the P-side bus bar 61p and N-side bus bar 61n than the other electronic components, such as the pre-drivers 32m and 32s. With this, the wiring length X between the first switching elements 31u1, 31v1 and 31w1 and the second switching elements 31u2, 31v2 and 31w2 and the smoothing capacitors 54m and 54s can be reduced, and thereby the inductance L between the P-side bus bars61p and N-side bus bar 61n can be reduced.

In addition, the switching time by the first switching elements 31u1, 31v1 and 31w1 and second switching elements 31u2, 31v2 and 31w2 can be reduced by the reduction of the inductance L of the P-side bus bar 61p and N-side bus bar 61n. Consequently, heat generation in the first switching elements 31u1, 31v1 and 31w1 and second switching elements 31u2, 31v2 and 31w2 is reduced and the cooling structure for cooling the first switching elements 31u1, 31v1 and 31w1 and second switching elements 31u2, 31v2 and 31w2 can be simplified. In this way, by the reduction of the inductance L between the P-side bus bar 61p and N-side bus bar 61n and the reduction of the switching time, the size of the electronic control device E1 can further be reduced.

In addition, in the present embodiment, the power supply line 61 has the P-side bus bar 61p and N-side bus bar 61n, and the P-side bus bar 61p and N-side bus bar 61n are arranged such that the exposed wiring parts (P-side board connection part 613p and N-side board connection part 613n in the present embodiment) facing the housing space S face each other.

In this way, in the present embodiment, the P-side bus bar 61p and N-side bus bar 61n are arranged facing each other. Consequently, it is possible to shorten the distance d between P-side bus bar 61p and N-side bus bar 61n, thereby reducing the inductance L between P-side bus bar 61p and N-side bus bar 61n. As a result, the smoothing capacitors 54m and 54s can be made smaller, and the size of the electronic control device E1 can be reduced more effectively.

In addition, in the present embodiment, the P-side bus bar 61p and N-side bus bar 61n are wirings formed in wide flat plate shapes and are arranged such that the wide side surfaces (P-side first plane part 61p1 and N-side first plane part 61n1 in the present embodiment) face each other.

In this way, in the present embodiment, the P-side bus bar 61p and N-side bus bar 61n are composed of wirings formed in wide flat plate shapes, and the P-side first plane part 61p1 and N-side first plane part 61n1 that are the above-mentioned wide side surfaces are arranged facing each other. With this, the inductance L between the P-side bus bar 61p and N-side bus bar 61n is reduced, and the size of the smoothing capacitors 54m and 54s can be reduced. As a result, the size of the electronic control device E1 can be reduced more effectively.

In addition, in the present embodiment, the P-side bus bar 61p and N-side bus bar 61n face each other at a distance closer than the width dimension (width W1 of the P-side first plane part 61p1 and N-side first plane part 61n1 in the present embodiment) or thickness dimension (width W2 of the P-side second plane part 61p2 and N-side second plane part 61n2 in the present embodiment) of the P-side bus bar 61p and N-side bus bar 61n.

In this way, in the present embodiment, the P-side bus bar 61p and N-side bus bar 61n face each other at a distance closer than the width W1 of the P-side first plane part 61p1 and N-side first plane part 61n1 or the width W2 of the P-side second plane part 61p2 and N-side second plane part 61n2. With this, the inductance L between the P-side bus bar 61p and N-side bus bar 61n is effectively reduced, and the size of the smoothing capacitors 54m and 54s are reduced further. As a result, the electronic control device E1 can be downsized even more effectively.

In addition, in the present embodiment, in the P-side bus bar 61p and N-side bus bar 61n, the distance X1 of a section where the wide side surfaces face each other (first region Q1 where P-side first plane part 61p1 and N-side first plane part 61n1 face each other in the present embodiment) is longer than the distance X2 of a section where the wide side surfaces do not face each other (P-side second plane part 61p2 and N-side second plane part 6 1n2 face each other).

In this way, in the present embodiment, the distance X1 of the first region Q1 where the P-side first plane part 61p1 and the N-side first plane part 61n1 face each other is longer than the distance X2 of the second region Q2 where the P-side second plane part 61p2 and the N-side second plane part 61n2 face each other. In this way, since the distance X1 of the first region Q1 where the P-side first plane part 61p1 and the N-side first plane part 61n1 face each other is set relatively long, the inductance L between the P-side bus bar 61p and N-side bus bar 61n can be reduced compared with the case where the distance X2 in the second region Q2 where the P-side second plane section 61p2 and N-side second plane section 61n2 face each other is set relatively long.

### SECOND EMBODIMENT

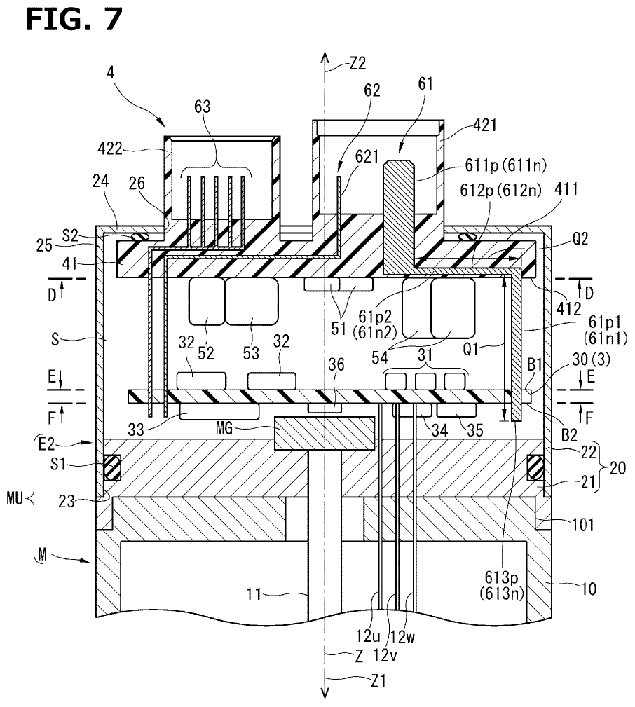

FIGS. 7 to 10 show a second embodiment of the electronic control device according to the present invention, and the configuration of the power supply line 61, namely, the P-side bus bar 61p and the N-side bus bar 61n of the electronic control device E1 of the first embodiment described above is changed. In addition, since the basic configuration other than such changes is the same as that of the first embodiment, the same symbols are applied to the same configuration as that of the first embodiment, and its explanation is omitted. FIG. 7 shows an electronic control device E2 according to the second

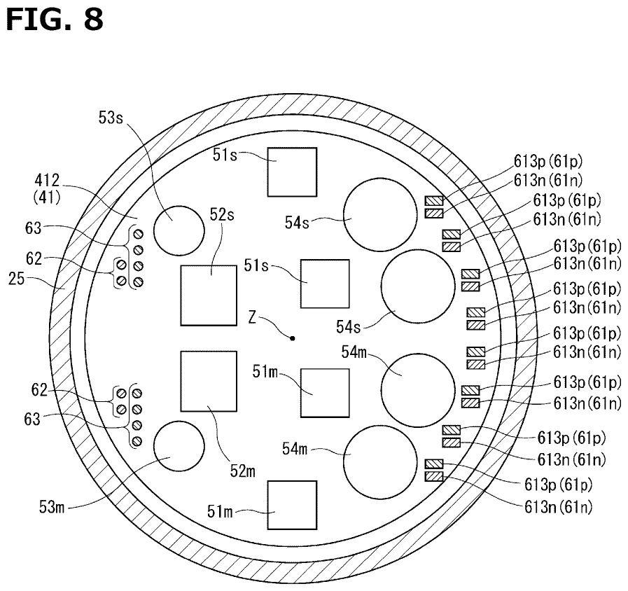

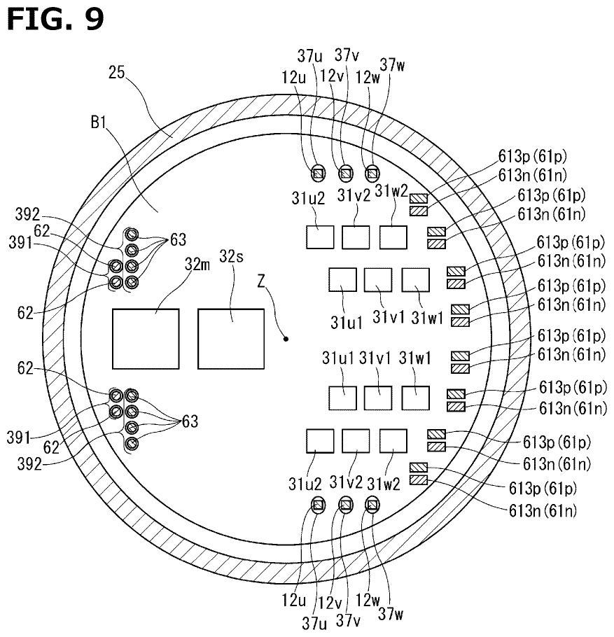

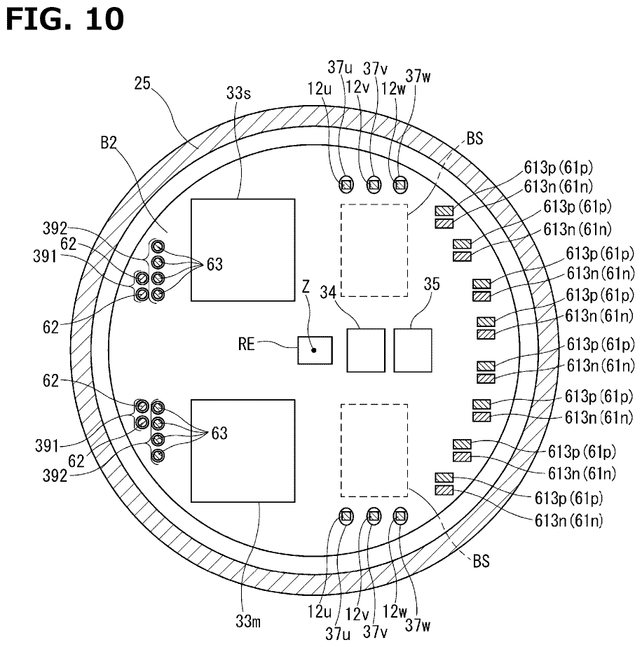

embodiment of the present invention, and is a sectional view of a motor unit MU which is cut the motor unit MU configured by integrating the electronic control unit E2 with the motor M along the rotational axis line Z of the motor M. FIG. 8 is a sectional view taken along a D-D line of FIG. 7, and there is shown a cross section of the electronic control device E2 viewed from the second side surface 412 side of the connector base 41. FIG. 9 is a sectional view taken an E-E line of FIG. 7, and there is shown a cross section of the electronic control device E2 viewed from the first surface B1 side of the circuit board 30. FIG. 10 is a sectional view taken along an F-F line of FIG. 7, and there is shown a cross section of the electronic control device E2 viewed from the second surface B2 side of the circuit board 30.

As shown in FIGS. 7 to 10, in the electronic control device E2 according to the present embodiment, the P-side bus bar 61p has a plurality of branched P-side branch portions 613px at the P-side board connection part 613p, and the N-side bus bar 61n has a plurality of branched N-side branch portions 613n at the N-side board connection part 613n. Then, similar to the first embodiment, the P-side branch portions 613px and N-side branch portions 613nx are configured such that the relatively wide plane parts, namely, the P-side first plane part 61p1 and N-side first plane part 61n1 face each other.

In addition, on the second side surface 412 of the connector base 41, a plurality of P-side bus bar insertion holes 45p through which the P-side branch portions 613px of the P-side board connection part 613p is inserted and a plurality of N-side bus bar insertion holes 45n through which the N-side branch portions 613nx of the N-side board connection part 613n is inserted are arranged outside of the smoothing capacitors 54m and 54s. Here, the P-side bus bar insertion holes 45p are paired with the respective N-side bus bar insertion holes 45n, and the P-side bus bar insertion holes 45p and N-side bus bar insertion holes 45n are alternately provided along the outer circumferential edge of the circuit board 30.

In other words, in the present embodiment, the plurality of branched P-side branch portions 613px and N-side branch portions 613nx are not gathered and arranged as a group of the P-side branch portions 613px and a group of the N-side branch portions 613nx, respectively, but are alternately arranged such that the pairs of the P-side branches 613px and N-side branches 613nx are adjacent to each other.

Moreover, similar to the first embodiment, P-side bus bar insertion holes 38p and the N-side bus bar insertion holes 38n are arranged such that the P-side board connection part 613p (P-side branch portions 613px) and the N-side board connection part 613n (N-side branch portions 613nx) are close to each other at a distance smaller than the width W1 of the relatively wide P-side first plane part 61p1 and N-side first plane part 61n1 of the P-side board connection part 613p (P-side branch portions 613px) and N-side board connection part 613n (N-side branch portions 613nx), or the width W2 of the relatively narrow P-side second plane part 61p2 and N-side second plane part 61n2 of the P-side board connection part 613p (P-side branch portions 613px) and N-side board connection part 613n (N-side branch portions 613nx).

In addition, on the first surface B1 of the circuit board 30, first switching elements 31u1, 31v1 and 31w1 and second switching elements 31u2, 31v2 and 31w2 are arranged in a so-called staggered arrangement such that the first switching elements 31u1, 31v1 and 31w1 are inside and the second switching elements 31u2, 31v2 and 31w2 are outside. Moreover, U-phase terminal insertion holes 37u, V-phase terminal insertion holes 37v, and W-phase terminal insertion holes 37w through which U-phase connection terminals 12u, V-phase connection terminals 12v, and W-phase connection terminals 12w that are U-phase, V-phase, and W-phase connection terminals (winding terminals) which are connected to the motor M are respectively inserted are formed on the outside of the second switching elements 31u2, 31v2 and 31w2 respectively, so as to penetrate through the first surface B1.

In addition, on the first surface B1 of the circuit board 30, in the area outside the first switching elements 31u1, 31v1 and 31w1 and the second switching elements 31u2, 31v2 and 31w2, relative to the rotation axis Z of the motor M (motor rotation shaft 11), in positions corresponding to the P-side bus bar insertion holes 45p and N-side bus bar insertion holes 45n in the connector base 41, a plurality of P-side bus bar insertion holes 38p and N-side bus bar insertion holes 38n through which P-side branch portions 613px and N-side branch portions 613nx are respectively inserted are formed in pairs, along the outer circumferential edge of the circuit board 30 in a state of penetrating through the first surface B1.

In other words, in the present embodiment, the plurality of branched P-side branch portions 613px and N-side branch portions 613nx are not gathered and arranged in a group of the P-side branch portions 613px and a group of the N-side branch portions 613nx respectively, but are alternately arranged such that the pairs of the P-side branch portions 613px and N-side branch portions 613nx are adjacent to each other.

As the above, in the present embodiment, the power supply line 61 has a P-side bus bar 61p and an N-side bus bar 61n, and the P-side bus bar 61p has a plurality of branched P-side branch portions 613px in the exposed wiring part (P-side substrate connection part 613p in the present embodiment) which faces the housing space S, and the N side bus bar 61n has a plurality of branched N-side branch portions 613nx in the exposed wiring portion (N-side substrate connection part 613n in the present embodiment) facing the housing space S, and the P-side branch portions 613px and N-side branch portions 613nx are arranged alternately.

In this way, in the present embodiment, the P-side bus bar 61P and N-side bus bar 61N are respectively provided with the plurality of the P-side branch portions 613Px and N-side branch portions 613Nx, and these P-side branch portions 613Px and N-side branch portions 613Nx are arranged alternately. With this, the facing area of the P-side bus bar 61P and N-side bus bar 61N is increased, and the inductance L between the P-side bus bar 61P and N-side bus bar 61N can be reduced. Consequently, it is possible to downsize the smoothing capacitors 54m and 54s, and thereby the size of the electronic control unit E1 can be reduced more effectively.

In addition, in the present embodiment, as an example, the P-side substrate connection part 613p and N-side substrate connection part 613n are branched into eight P-side branch portions 613px and N-side branch portions 613nx, respectively, and the eight P-side branch portions 613px and N-side branch portions 613nx are arranged in an arc shape along the outer circumferential edge of the connector base 41 and the circuit substrate 30. However, the P-side branch portions 613px and N-side branch portions 613nx are not limited to the eight branch types described above or to the circular arrangement along the outer circumferential edge described above, and can take any number of branches or any arrangement, depending on the specifications of the electronic control device E2, as shown in the following variations.

### (First Variation)

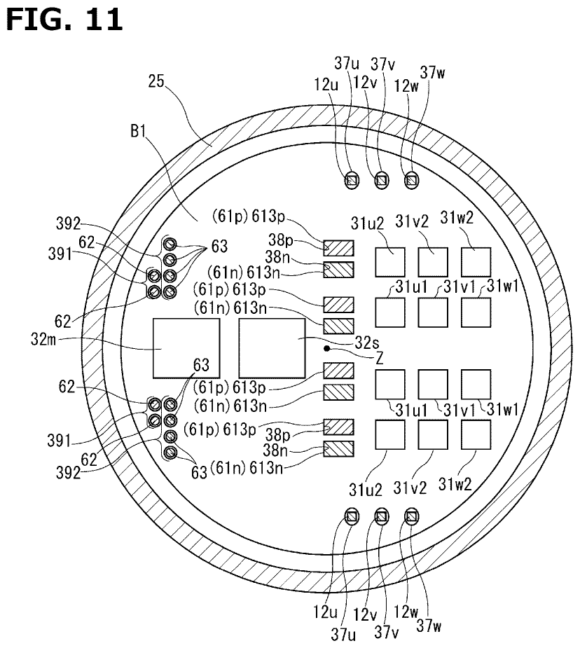

FIG. 11 shows a first variation of the second embodiment of the present invention and is a sectional view of an electronic control device E21 which corresponds to the cross section taken along the E-E line of FIG. 7.

As shown in FIG. 11, the P-side branch portions 613px and N-side branch portions 613nx may be arranged in a straight line along the radial direction in the center of the circuit board 30.

### (Second Variation)

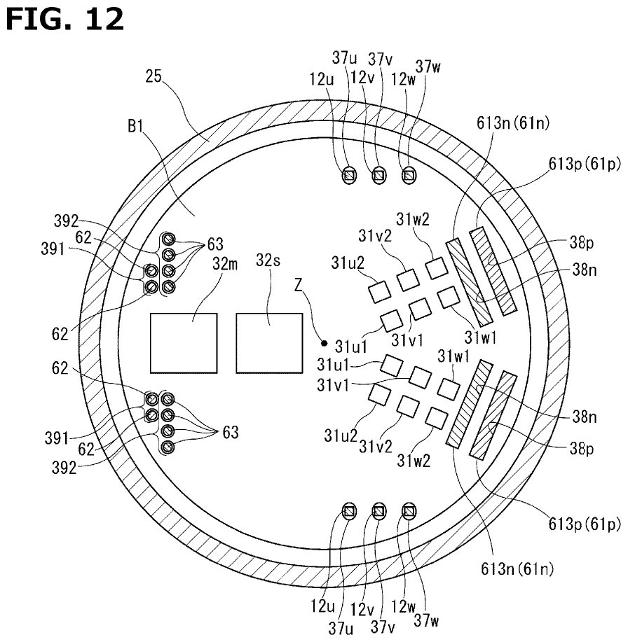

FIG. 12 shows a second variation of the second embodiment of the present invention and is a sectional view of an electronic control device E22 which corresponds to the cross section taken along the E-E line of FIG. 7.

As shown in FIG. 12, the P-side substrate connection part 613p and N-side substrate connection part 613n may be branched into two P-side branch portions 613Px and N-side branch portions 613Nx, which is less than the eight branching patterns of the second embodiment described above. In addition, in this case, the P-side branch portions 613px and N-side branch portions 613nx may be arranged in pairs facing each other, and the P-side branch portions 613px and N-side branch portions 613nx may be arranged in a so-called “V” shape along the outer circumferential edge of the circuit board 30.

The present invention is not limited to the configurations and forms shown in the above embodiments as an example, and can be freely changed according to the specifications, cost and the like of an electronic control device to which the present invention is applied, as long as it can achieve the working effects of the present invention.

In particular, in the present invention, it is sufficient that a capacitor, which requires a relatively large mounting area as compared with other electronic components, is arranged on the connector module side, and the other electronic components can be arranged on the connector module or circuit board as desired. In addition, it goes without saying that the shapes of the P-side bus bar 61p and N-side bus bar 61n which constitute the power supply line 61 can also be changed as desired according to the power conversion circuit configured on the circuit board.

In addition, although in the present embodiments mentioned above, the inverter circuit, which is a power conversion circuit, is formed on a power conversion circuit board (circuit board 30), the inverter circuit may be formed on a so-called power conversion circuit module which is packaged together with other functional elements, including power conversion functional elements.

### (Other Technical Ideas)

In the following, the technical ideas other than the invention described in the scope of the claims will be explained.
(a) The electronic control device described in claim 1 is characterized in that the power supply line is composed of conductive bus bars, the bus bars are provided extending through an inside of the connector module from the connector port so as to face the housing space of the casing from the second side surface of the connector base and are connected to the power conversion circuit module, the power conversion circuit module is an electronic component which is packaged together with other functional elements, including power conversion functional elements, and on the second side surface of the connector module, the power conversion functional elements in the package are arranged closer to exposed wiring portions of the bus bars which face the housing space than the other functional components.
(b) The electronic control device described in claim 1 is characterized in that the power conversion system has the power conversion circuit module and has a control board on which a microcomputer that controls the power conversion circuit module or a drive circuit component that outputs a drive signal to the power conversion circuit module is mounted, the power supply line is composed of conductive bus bars, the bus bars are provided extending through the inside of the connector module from the connector port, so as to face the housing space of the casing from the second side surface of the connector base and are connected to the power conversion circuit module and the control board, and on the second side surface of the connector module, the power conversion circuit module is arranged closer to the exposed wiring portions of the bus bars which face the housing space than electronic components mounted on the control board.
(c) The electronic control device described in claim 1 is characterized in that on the second side surface of the connector module, a capacitor and coil component for noise removal are mounted together with a capacitor for power smoothing to configure a noise filter circuit.
(d) The electronic control device described in claim 1 is characterized in that the rotating electric machine has at least two windings, the power conversion circuit system is configured to supply drive power to each of the windings, the connector port, the capacitors, and the power conversion circuit are configured as a power supply system for each of the windings, and it is possible to drive the rotating electric machine by supplying power to the corresponding windings through at least one power supply system.
(e) The electronic control device described in claim 1 is characterized in that the power supply line is composed of conductive bus bars made of aluminum, first end portions of the bus bars are located inside the connector port, the middle parts of the bus bars pass through the inside of the connector module, and second end portions of the bus bars face the housing space of the casing from the second side surface of the connector base and are located in the housing space.
(f) The electronic control device described in claim 1 is characterized in that the rotating electric machine has at least two windings, the power conversion circuit system is configured to supply drive power to each of the windings, the connector port, the capacitors and the power conversion circuit are configured as a power supply system for each of the windings, the power conversion circuit is formed on the power conversion circuit board, the power conversion circuit board is a board on which control circuit components including a microcomputer and drive circuit components that output drive support signals based on the calculation processing results of the microcomputer to the power conversion circuit are mounted, the power conversion circuit components, control circuit components and drive circuit components of the power conversion circuit are provided for each of the windings as a drive system capable of driving the rotating electric machine for each of the windings on the board, and at least the power conversion components, the microcomputer, and some of the drive circuit components are arranged symmetrically on the board between the drive systems from the perspective of geometric structure.
(g) The electronic control device described in the above (f) is characterized in that the board is a single multilayer printed circuit board.
(h) The electronic control device described in claim 1 is characterized in that a capacitor holder that holds the capacitor is provided at the mounting position of the capacitor related to the power smoothing on the second side surface.
(i) The electronic control device described in the above (h) is characterized in that the capacitor is held in the capacitor holder such that the longitudinal direction of the capacitor is in the direction of the rotation axis of the rotating electric machine.

1. An electronic control device including a power conversion system which converts power of a power source into drive power to drive a rotating electrical machine, comprising:
a power conversion circuit module or power conversion circuit board on which a power conversion circuit constituting the power conversion system is formed;
a casing which includes a housing space thereinside and houses the power conversion circuit module or power conversion circuit board;
a connector module which includes a connector base which is housed in the housing space together with the power conversion circuit module or power conversion circuit board, and a connector port which is formed on a first side surface of the connector base and protrudes outside the casing; and
a capacitor which is mounted on a second side surface of the connector base, which is positioned on an opposite side of the first side surface, and is used for power smoothing or noise reduction of a power supply line leading from the connector port to the power conversion circuit.

2. The electronic control device according to claim 1, wherein the power supply line is composed of conductive bus bars,
wherein the bus bars are provided extending through an inside of the connector module from the connector port so as to face the housing space from the second side surface of the connector base, and are connected to the power conversion circuit module or power conversion circuit board,
wherein on the second side surface of the connector module, in addition to the capacitor, other electronic components are mounted, and
wherein on the second side surface of the connector module, the capacitor is arranged closer to the bus bars facing the housing space than the other electronic components.

3. The electronic control device according to claim 1, wherein the power supply line is composed of conductive bus bars,
wherein the bus bars are provided extending through an inside of the connector module from the connector port so as to face the housing space from the second side surface of the connector base, and are connected to the power conversion circuit board,
wherein the power conversion circuit includes a plurality of switching elements,
wherein the power conversion circuit board is mounted with other electronic components together with the plurality of switching elements, and
wherein on the second side surface of the connector module, at least one of the plurality of switching elements is arranged closer to exposed wiring portions of the bus bars which face the housing space than the other electronic components.

4. The electronic control device according to claim 1, wherein the power supply line includes a P-side bus bar and an N-side bus bar, and
wherein the P-side bus bar and N-side bus bar are arranged such that exposed wiring portions of the respective P-side bus bar and N-side bus bar which face the housing space face each other.

5. The electronic control device according to claim 4, wherein the P-side bus bar and N-side bus bar are wirings formed in wide flat plate shapes and are arranged such that wide side surfaces of the respective P-side bus bar and N-side bus bar face each other.

6. The electronic control device according to claim 5, wherein the P-side bus bar and N-side bus bar are positioned facing each other at a distance closer than a width dimension or thickness dimension of each of the P-side bus bar and N-side bus bar.

7. The electronic control device according to claim 6, wherein the P-side bus bar and N-side bus bar are arranged such that a distance of a section where the wider side surfaces face each other is longer than a distance of a section where the wider side surfaces do not face each other.

8. The electronic control device according to claim 1, wherein the power supply line includes a P-side bus bar and an N-side bus bar,
wherein the P-side bus bar has a plurality of branched P-side branch portions at an exposed wiring portion of the P-side bus bar which faces the housing space,
wherein the N-side bus bar has a plurality of branched N-side branch portions at an exposed wiring portion of the N-side bus bar which faces the housing space, and
wherein the P-side branch portions and N-side branch portions are arranged alternately.
